(19) United States
(12) Patent Application Publication
(10) Pub. No.: US 2005/0179852 A1
(43) Pub. Date: Aug. 18, 2005

(54) Electro-optical device, method for manufacturing the same, and electronic device

(75) Inventor: Hideyuki Kawai, Fujimi-cho (JP)

Correspondence Address: OLIFF & BERRIDGE, PLC, P.O. BOX 19928, ALEXANDRIA, VA, 22320, US

(73) Assignee: Seiko Epson Corporation, Tokyo (JP)

(21) Appl. No.: 11/041,240

(22) Filed: Jan. 25, 2005

(30) Foreign Application Priority Data
Feb. 12, 2004 (JP) 2004-034766

(51) Int. Cl. G02F 1/1339

(52) U.S. Cl. 349/153

(57) ABSTRACT

Aspects of the invention can provide an electro-optical device and a method for manufacturing the same device, as well as an electronic device, which prevent the infiltration of moisture through, especially, a sealing part, reduction of durability of a display element, and the like, due to moisture, and life shortening of such an element due to the reduced durability. The electro-optical device can include a pair of plastic substrates with a display element in between. The periphery of the plastic substrates can be sealed by welding, which configures a sealing part.

### BACKGROUND

Aspects of the invention can relate to an electro-optical device including a pair of plastic substrates with a display element in between and a method for manufacturing the same device, as well as an electronic device.

As a related art display device having a configuration of a pair of substrates with a display element in between, there are devices, such as liquid crystal display devices, organic EL devices, electrophoretic display device, and the like. Substrates used for such devices are mainly glass. However, with the spread of portable terminal devices, such as PDAs and cellular phones in recent years, the use of plastic substrates has been being considered as the display device used for such terminal devices in terms of flexibility, unbreakableness, lightness, etc.

Nevertheless, in the above display devices using plastic substrates, there has been a problem of short life due to low durability of the display element and a drive circuit for driving the display element, etc., which is attributed to the effect of moisture permeated through the substrates, whose ability to block atmospheric moisture is insufficient.

As a technique to solve such a problem, a method has been proposed for controlling moisture permeability by forming a low-moisture permeable film, such as silicon oxide, silicon nitride or silicon oxynitride film, etc., on the surface of film substrates by deposition methods, such as sputtering, vacuum CVD, plasma CVD, and the like. See, for example, Japanese Unexamined Patent Publication No. 2003-105541.

Further, there has been another proposal of a method using a substrate of a transparent composite film having a transparent resin layer comprising a hydrophilic macromolecule material, such as vinyl alcohol-vinyl acetic acid copolymer (PVA) or ethylene-vinyl alcohol copolymer (EVOH), and the like, and a transparent inorganic thin film, such as silicon oxide, aluminum oxide, magnesium oxide, and the like. See, for example, Japanese Unexamined Patent Publication No. 2003-202603.

However, even if the moisture permeability of the plastic substrate is sufficiently controlled using the methods described above, the moisture infiltrating from, for example, a sealing part 2 between and on the periphery (circumference) of plastic substrates 1 and 1, as shown in FIG. 6, cannot be blocked. In addition, in FIG. 6, a reference numeral 3 is a display element unit; 4 is a low-moisture permeable film; and 5 is a sealant made of resin, etc.

Therefore, in order to solve such a problem, there have been proposals such as addition of fluorine compound to the sealant 5 (refer to Japanese Unexamined Patent Publication No. 58-40529, for example) and enclosure of filler into a region sectioned by an inner sealing part and an outer sealing part, which is a double-sealing structure (refer to Japanese Unexamined Patent Publication No. 2001-264777, for example).

### SUMMARY

However, in related art display devices using a pair of plastic substrates, it has been difficult to sufficiently block the moisture infiltrating from the sealing part on the periphery of the substrates even with the methods described above.

Aspects of the invention have been developed under the consideration of such a problem and is intended to provide an electro-optical device (display device) and a method for manufacturing the same device, as well as an electronic device, which prevent the infiltration of moisture through, especially, the sealing part; reduction of durability of the display element, etc. due to moisture; and life shortening of such an element due to the reduced durability.

To achieve the above purpose, the electro-optical device according to the invention can take a configuration of an electro-optical device having a pair of plastic substrates and a display element between the pair of plastic substrates, the periphery of the plastic substrates can be sealed by welding.

With the above electro-optical device, wherein the periphery of the plastic substrates can be sealed by welding for higher sealability, moisture permeation, that is, moisture infiltration, from the welded sealing part can be highly controlled, which therefore prevents reduction of durability of the display element, etc. due to moisture, and life shortening of such an element due to the reduced durability. Further, in the above electro-optical device, it is preferable that the pair of plastic substrates are welded and sealed along the entire periphery. With such a method, sealability becomes much higher and more reliable, which means that the preventiveness for reduction of durability, etc. becomes more reliable.

In addition, in the above electro-optical device, it is preferable that a low-moisture permeable film can be provided on the inner surface of each of the pair of plastic substrates. Thus, moisture permeation not only through the welded sealing part but also from the plastic substrates themselves can be controlled, which leads to a higher preventiveness for reduction of durability of display elements, etc. due to moisture.

Furthermore, in the above electro-optical device, it is preferable that both of the pair of plastic substrates have flexibility. Thus, the electro-optical device can be made flexible as a whole.

Also, in the above electro-optical device, the display element can be an electrophoretic element. In an electrophoretic element, because of a change in (reduction of) electrifiability and decentralized stabilization of particles which are electrified due to moisture, movement of such particles is worsened and therefore display performance is degraded. However, in the above electro-optical device, excellent display performance can be maintained for a long time because, as described above, the improved sealability highly controls the infiltration of moisture.

Moreover, in the above electro-optical device, the display element can be an EL element. In an organic EL element using an organic luminous layer as an EL element, display properties are badly degraded when the organic luminous layer and a cathode, which are susceptible to moisture, contact with moisture. However, in the above electro-optical device, excellent display performance can be maintained for a long time because, as described above, the improved sealability highly controls the infiltration of moisture.

The exemplary method for manufacturing an electro-optical device according to the invention is a method for manufacturing an electro-optical device having a pair of plastic substrates with a display element in between, can include the steps of bonding the pair of plastic substrates with the display element in between, and welding the periphery of the bonded pair of plastic substrates.

With the above method for manufacturing an electro-optical device, wherein the periphery of the pair of plastic substrates is sealed by welding for higher sealability, moisture permeation, that is, moisture infiltration, from the welded sealing part can be highly controlled, which therefore prevents reduction of durability of the display element, etc. due to moisture, and life shortening of such an element due to the reduced durability.

Further, in the above method for manufacturing an electro-optical device, it is preferable that the welding is performed by means of laser irradiation or ultrasonication. Thus, pinpoint heating becomes possible using such a treatment, and therefore the substrates can be welded together with a narrow sealing width without giving any effect of heat on the display element, etc.

In addition, in the above method for manufacturing an electro-optical device, it is preferable that the pair of plastic substrates are welded with the periphery being clamped. Thus, the region between the substrates is better sealed and encapsulated by such a welding method because the peripheral region between the substrates, which makes the sealing part, is closely adhered by clamping.

The electronic device according to-the invention can include the electro-optical device described above or the electro-optical device obtained by using the manufacturing method described above. With the above electronic device, having the electro-optical device in which, as described above, life shortening due to the reduction of durability is prevented, the life of the above electronic device can be prolonged as a whole.

### BRIEF DESCRIPTION OF THE DRAWINGS

The invention will be described with reference to the accompanying drawings, wherein like numerals reference like elements, and wherein:

FIG. 1A is a cross-sectional side view drawing and FIG. 1B is a top view drawing of an electro-optical device according to the invention;

FIG. 2A to C are schematic drawings of an electrophoretic display device which configures a display element unit;

FIGS. 3A and B are explanatory drawings of a method for manufacturing an electro-optical device according to the invention;

FIG. 4 is a perspective view of an electronic device according to the invention;

FIG. 5 is a perspective view of an electronic device according to the invention; and

FIG. 6 is a cross-sectional side view drawing of an example of the related art display device.

### DETAILED DESCRIPTION OF PREFERRED EMBODIMENTS

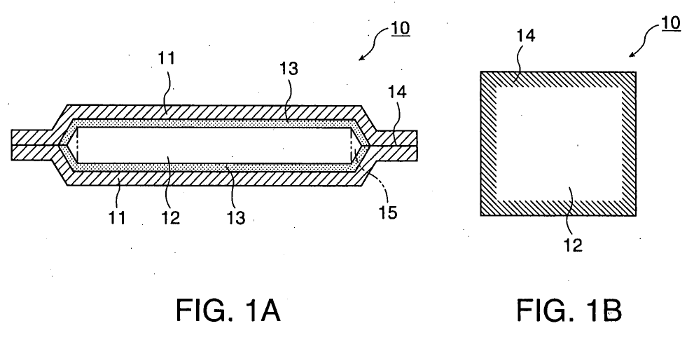

The present invention will now be described in detail. FIGS. 1A and B are drawings of an exemplary embodiment of an electro-optical device according to the invention, and a reference numeral 10 in FIG. 1 is the electro-optical device. The electro-optical device 10 can include a pair of plastic substrates 11 and a display element unit 12, which includes a number of display elements, in between a pair of plastic substrates 11.

Each plastic substrate 11 is a generally rectangular film with a thickness of approximately 200 μm, which gives flexibility. The material of the plastic substrate 11 is not especially specified only if it is thermoplastic material and can be processed by welding described below. However, in the electro-optical device 10, it is preferable to select a material, especially for the substrate on the display surface (the surface to be observed), having a high optical transmissivity. As the material of the plastic substrate 11, polyester such as polyethylene terephthalate (PET), polyethylene naphthalate (PEN), etc., as well as polyethylene (PE), polystyrene (PS), polypropylene (PP), polycarbonate (PC), polyetheretherketone (PEEK), polyethersulfone (PES), acryl or polyacrylate can be named specifically in the case of, for example, employing ultrasonication as the welding treatment. Especially, non-crystalline resin materials such as polycarbonate (PC), polystyrene (PS) and polyethersulfone (PES) are preferable because of such materials' high suitability for welding.

On the inner surface of each plastic substrate 11, a low-moisture permeable film 13 can be provided. The low-moisture permeable film 13 can be made of inorganic material, such as silicon oxide, silicon nitride or silicon oxynitride film, etc., and formed on the surface (inner surface) of the plastic substrate 11 by means of deposition methods such as sputtering, vacuum CVD, plasma CVD, etc. The above low-moisture permeable film 13 is formed with a thickness of, for example, approximately 0.1 μm, which is sufficiently thinner than that of the plastic substrate 11, and therefore flexible.

Further, the plastic substrates 11 and 11 are sealed along the periphery by welding, with the display element unit 12 in between the low-moisture permeable films 13 and 13, and thus a sealing part 14 is formed. In the present embodiment, as shown in FIG. 1B, the periphery (circumference) is entirely welded to form the sealing part 14, and thus the sealing part 14 encircles the display element unit 12 along the entire circumference.

The above sealing part 14 is formed by welding employing laser irradiation or ultrasonication, which is described below. That is, the welded regions on the plastic substrates 11 and 11 are melted by being heated. Then, after being cooled and solidified, the melted regions are closely adhered to each other and integrated into the sealing part 14.

Unlike the adhesion using an adhesive, the sealing part 14 formed in the above manner is formed without an intermediary of foreign materials between the plastic substrates 11 and 11 but directly coupled to each other, which provides a coupling with a high airtightness (sealability). In addition, for higher airtightness (sealability) of the sealing part 14, it is preferable to form the plastic substrates 11 and 11 from thermoplastic resin of the same material. Further, when different materials are used, the use of materials having close melting temperatures is preferred.

Here, there is no low-moisture permeable film 13 between the plastic substrates 11 and 11 at the sealing part 14, as shown in FIG. 1A. This is because the low-moisture permeable film 13, whose thickness is very thin as, for example, approximately 0.1 μm, is broken into very fine pieces and taken into the melted plastic substrates 11 and 11 when the plastic substrates 11 and 11 are melted by welding. In addition, for easier welding, the low-moisture permeable film 13 can be formed avoiding the region expected to become the sealing part 14 or the low-moisture permeable film 13 can be removed from the same region in advance.

Further, especially for the sealing part 14, in terms of enhancing the sealability in the above manufacturing step, a sealing member 15 made of resin, etc. can be provided on the inside of the sealing part 14 (on the side of the display element unit 13), as shown with medium two-dot chain lines in FIG. 1A.

In the exemplary embodiment according to the invention, the display element unit 12 configures an electrophoretic display device which can include a number of electrophoretic elements.

An electrophoretic display device can include a pair of substrates between which electrophoretic dispersion liquid containing a liquid-phase dispersion medium and electrophoretic particles is encapsulated, and utilizes a variation in the distribution of electrophoretic particles caused by applying a voltage to the electrophoretic dispersion liquid.

As such an electrophoretic display device, the embodiment employs an electrophoretic display device which is configured by encapsulating, especially, the electrophoretic dispersion liquid into a microcapsule to be housed between a pair of substrates (a microcapsular electrophoretic display device).

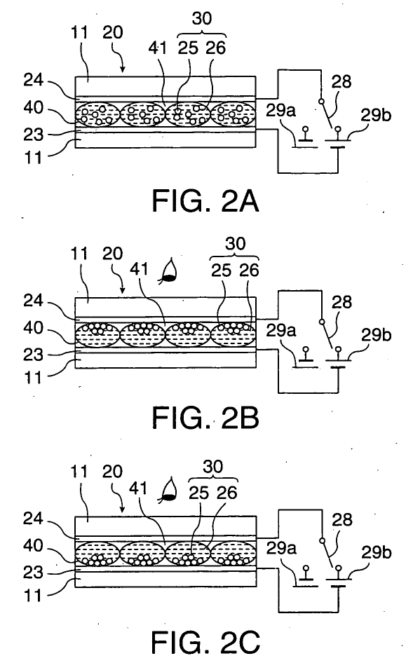

FIG. 2A is a schematic drawing of a microcapsular electrophoretic display device which configures the display element unit 12. An electrophoretic display device 20 can include an electrode 23 formed on one of the plastic substrates 11 and a transparent electrode 24 formed on the other plastic substrate 11. Between the electrode 23 and the transparent electrode 24, a microcapsule 40 and a binder 41, which is provided according to need, are housed. In addition, FIG. 2A is a cross-sectional view of the relevant region of the electrophoretic display device 20. Further, in FIG. 2A to C, the low-moisture permeable film 13 on the inner surface of the plastic substrate 11 is omitted.

In the microcapsule 40, electrophoretic dispersion liquid 30 containing a liquid-phase dispersion medium 26 and electrophoretic particles 25 which are dispersed within the liquid-phase dispersion medium 26, is encapsulated. With one microcapsule 40, for example, a single electrophoretic element can be formed. The electrophoretic particles 25 are positively or negatively electrified in advance, and the liquid-phase dispersion medium 26 and the electrophoretic particles 25 are colored differently to each other.

To the electrophoretic display device 20, voltage sources 29a and 29b, which are provided for applying voltages in opposite directions, are coupled with an intermediary of a changeover switch 28. That is, the electrode 23 can be coupled to one end of each of the voltage sources 29a and 29b, and the transparent electrode 24 is coupled to the other end of each of the voltage sources 29a and 29b with an intermediary of the changeover switch 28. Further, in the embodiment, the changeover switch 28 and the voltage sources 29a and 29b are coupled to one another with an intermediary of wiring on the outside of the plastic substrates 11 and 11.

With such a coupling method, the direction of voltage applied between the electrodes 23 and 24 can be changed by using the changeover switch 28. Further, by changing the direction of a voltage applied so as to gather the electrophoretic particles 25 on the side of a desired electrode, desired display can be achieved. That is, when the electrophoretic particles 25 are, for example, positively electrified, the electrophoretic particles 25 can be gathered on the side of the transparent electrode 24, which is close to the observer, by applying a voltage from the voltage source 29a, as shown in FIG. 2B. Under such circumstances, the observer sees the color of the electrophoretic particles 25. On the other hand, as shown in FIG. 2C, the electrophoretic particles 25 can be gathered on the side of the electrode 23, which is far from the observer, by applying a voltage from the voltage source 29b. Under such circumstances, the observer sees the color of the liquid-phase dispersion medium 26. When the electrophoretic particles 25 are negatively electrified, the direction in which the particles move becomes opposite to the above description.

As described above, when the configuration shown in FIG. 2A is employed, two colors can be displayed corresponding to the direction of voltage application. Therefore, by applying the configuration shown in the same figure to, for example, one pixel and arranging the pixel in a matrix, desired display can be shown on the electrophoretic display device 20.

That is, with the provision of the display element unit 12 between the pair of plastic substrates 11 and 11, the electrophoretic display device 20 described above becomes the electro-optical device 10 according to the invention. Further, in the exemplary embodiment, the wiring is drawn out from a through-hole formed on, for example, one of the plastic substrates 11, and coupled to the changeover switch 28 as well as the voltage sources 29a and 29b.

Next, based on the method for manufacturing the electro-optical device 10 (electrophoretic device 20) having such a configuration, an exemplary embodiment of the method for manufacturing an electro-optical device according to the invention will now be described.

Firstly, two plastic substrates 11 are prepared and the low-moisture permeable film 13 made of silicon oxide, silicon nitride or silicon oxynitride film, etc. is formed on one surface (inner surface) of each of the plastic substrates by means of deposition methods such as sputtering, vacuum CVD, plasma CVD, etc.

Secondly, from a substrate used for a printing, on which a TFT element is formed as, for example, a thin film element, the TFT element is separated and printed onto the inner surface (low-moisture permeable film 13) of one of the plastic substrates 11. Thus, an active matrix TFT circuit (not illustrated) is formed. In addition, a technique disclosed in Japanese Unexamined Patent Publication No. 11-251517 can be applied to the formation of such an active matrix TFT circuit. Further, the active matrix TFT circuit can be naturally formed within a region excluding the periphery (circumference) of the plastic substrate 11, that is, inside the sealing part 14 shown in FIGS. 1A and B.

Thirdly, the electrode 23, shown in FIG. 2A to C, can be formed on the inner surface (on the side of the active matrix TFT circuit) of the plastic substrate 11 having the active matrix TFT circuit, and the transparent electrode 24 is formed on the inner surface (on the side of the low-moisture permeable film 13) of the other plastic substrate 11. The electrode 23 and the transparent electrode 24 are formed by means of sputtering, evaporation, etc. In addition, the electrode 23 on the side of the active matrix TFT circuit is especially patterned so as to correspond to each pixel, which is regarded as a pixel electrode.

Further, apart from the above manufacturing step, the microcapsule 40 and the binder 41, which are shown in FIG. 2A to C, are mixed together so as to prepare coating liquid.

Then, the above coating liquid is applied on the inner surface of one of the plastic substrates 11. However, a mask must be put on the periphery, which is to become the sealing part 14, of the plastic substrate 11 in advance so as to block the coating liquid. Alternatively, the coating liquid can be wiped off from the periphery after applying on the entire surface.

Furthermore, when the sealing member 15 is provided in terms of enhancing the sealability, the sealing member 15 made of resin, etc. must be provided, on one or both of the plastic substrates 11, inside the region which is to become the sealing part 14.

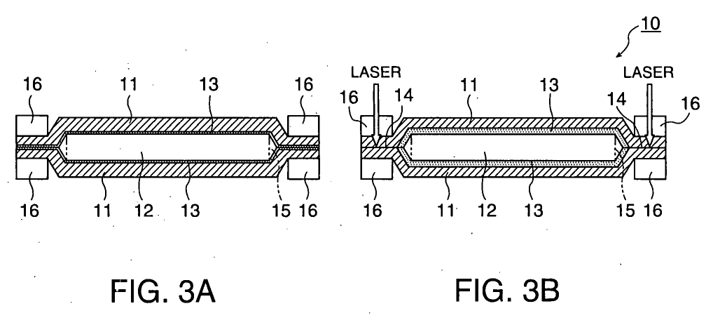

Next, the plastic substrate 11, on which the microcapsule 40 and the binder 41 (coating liquid) are provided, and the other plastic substrate 11 are bonded with the display element unit 12 in between, as shown in FIG. 3A.

Then, the periphery of the plastic substrates 11 and 11 is clamped by being sandwiched from above and below with clamping members 16 and 16 so that the inner surfaces closely contact with each other. As the clamping member 16, a publicly known clamping block, etc., which mechanically pressurizes and clamps, is used.

Then, under the state described above, the pair of plastic substrates 11 and 11 are welded along the periphery. As the welding method, laser irradiation and ultrasonication, as well as, for example, hot-plate heating and infrared irradiation can be employed. Especially, laser irradiation and ultrasonication are preferable because pinpoint heating can be achieved, and therefore the substrates 11 and 11 can be welded together with a narrow sealing width without giving any effect of heat on the display element unit 12, etc.

When laser irradiation is employed as the welding method, the clamping member 16 must be a material which transmits laser beams, that is, an optical-transmissive material. Further, for the plastic substrates 11 and 11, a laser-transmissive substrate is prepared as one of the plastic substrates 11, and a laser-absorptive substrate is prepared as the other plastic substrates 11 so that melting occurs at the coupling part of the plastic substrates. Here, for the laser-absorptive plastic substrate 11, coloring matters such as pigments, dyes, etc. can be added, according to need, for adjustment of light absorption properties. In addition, by coloring only the part to be welded (the region expected to become the sealing part 14), light absorptivity can be given selectively to the same part.

Conditions for laser irradiation (laser irradiation density, laser beam-feeding speed, etc.) are determined appropriately based on the conditions of the plastic substrates 11 and 11 to be used, such as material, thickness, light absorption properties, melting temperature, desired sealing width, and the like.

The types of available laser beams include yttrium aluminum garnet crystal (YAG) laser [wavelength: 1064 nm], laser diode (LD) [wavelength: 808 nm, 840 nm and 940 nm], etc.

When a laser beam is irradiated from the side of the laser-transmissive plastic substrate 11 under the conditions described above, as shown in FIG. 3B, the laser beam transmitted through the laser-transmissive plastic substrate 11 reaches the surface of the laser-absorptive plastic substrate 11. Then, on the laser-absorptive plastic substrate 11 which have absorbed the laser beam upon receiving the laser beam, the surface (inner surface) generates heat and causes melting, which accompanies heat generation and melting of the laser-transmissive plastic substrate 11 due to heat conduction. As a result of such processes of laser beam absorption, heat generation and heat conduction, the laser-irradiated region of the pair of upper and lower plastic substrates 11 and 11 is melted. Then, the heat generation stops when the laser irradiation is stopped, and the melted region is solidified by being cooled to a room temperature. Thus, the plastic substrates 11 and 11 are welded.

Further, by giving the above welding treatment for the entire periphery of the plastic substrates 11 and 11, the sealing part 14 which encircles the display element unit 12 can be formed as shown in FIG. 1B.

In addition, when the plastic substrates 11 and 11 are melted by welding, the low-moisture permeable film 13, formed on the region where the sealing part 14 is to be formed, is broken into very fine pieces and taken into the melted plastic substrates 11 and 11, because the film thickness can be extremely thin as described above.

Furthermore, when ultrasonication is employed as the welding method, a resonator (horn) is used as the clamping member 16 in FIG. 3A. By clamping the periphery of the plastic substrates 11 and 11 with the resonators sandwiching from above and below, the inner surfaces of the plastic substrates closely contact with each other. In addition, it is preferable to use the same material for both of the plastic substrates 11 and 11, as described above. Further, when different materials are used, the use of materials having close melting temperatures, specifically with a melting temperature difference of 22 degrees Celsius or less, is preferred. If the melting temperature difference exceeds, for example, 22 degrees Celsius, the resin with the lower melting temperature melts out and does not generate enough heat, which prevents the plastic substrate 11 with the higher melting temperature from melting easily.

When vibration energy is concentrated, using resonators (horns) as the clamping members 16 under the above conditions, onto the periphery (circumference) of the plastic substrates 11 and 11, the vibration energy is converted into frictional heat, which causes heat generation at the region subjected to the vibration energy, increasing the temperature of the same region on the plastic substrates 11 and 11 up to the melting temperature. Then, the heat generation stops when ultrasonication is stopped, and melted region is solidified by being cooled to a room temperature. Thus, the plastic substrates 11 and 11 are welded, the same as shown in FIG. 3B.

Further, by giving the above welding treatment along the entire periphery of the plastic substrates 11 and 11 at a time, the sealing part 14 which encircles the display element unit 12 can be formed, in the same manner as in the case of laser irradiation, as shown in FIG. 1B. In addition, when the plastic substrates 11 and 11 are melted by welding, the low-moisture permeable film 13, formed on the region where the sealing part 14 is to be formed, is broken into very fine pieces and taken into the melted plastic substrates 11 and 11, in the same manner as in the case of laser irradiation.

In the electro-optical device 10 obtained as described above, since the periphery of the plastic substrates 11 and 11 is entirely sealed by means of welding for higher sealability, moisture permeation, that is, moisture infiltration, from the welded sealing part 14 can be highly controlled, which therefore prevents reduction of durability of the display element, etc. due to moisture; and life shortening of such an element due to the reduced durability, leading to a longer life. In addition, since not only moisture permeation but also oxygen permeation can be prevented, degradation of the display element unit 12 and wiring due to oxidation can be reduced or prevented as well.

Further, since the electro-optical device 10 has the low-moisture permeable film 13 on each inner surface of the plastic substrates 11 and 11, moisture permeation not only through the welded sealing part 14, but also from the plastic substrates 11 themselves can be controlled, which leads to a higher preventiveness for reduction of durability of the display element, etc. due to moisture.

Furthermore, since both of the pair of plastic substrates 11 and 11 are flexible films, the electro-optical device 10 can also be made flexible as a whole.

Also, since the electro-optical device 10 according to the exemplary embodiment is applied to the electrophoretic display device 20 by configuring the display element unit 12 employing electrophoretic elements, it is possible to prevent the degradation of display performance caused by a worsened movement of the electrophoretic particles 25 due to a change in (reduction of) electrifiability and decentralized stabilization of the electrophoretic particles 25 which are electrified by moisture. Therefore, excellent display performance can be maintained for a long time.

On the other hand, with the method for manufacturing the electro-optical device 10, a longer life for display properties can be expected because of, as described above, the preventiveness for reduction of durability of the display element unit 12, etc. due to moisture, as well as life shortening of such an elements due to the reduced durability.

Further, since welding is performed by laser irradiation or ultrasonication, pinpoint heating can be achieved by such a treatment, and therefore the plastic substrates 11 and 11 can be welded together with a narrow sealing width without giving any effect of heat on the display element unit 12, etc.

Furthermore, since the pair of plastic substrates 11 and 11 are welded with the periphery clamped, the region between the plastic substrates 11 and 11 is better-sealed and encapsulated by such a welding method.

In addition, it should be understood that the invention is not limited to the above embodiment and can be varied in different ways unless the essence of the invention is lost. For example, the above embodiment employs a configuration of an electrophoretic display device which comprises a number of electrophoretic elements as the display element unit 12 and shows an example of applying the electro-optical device according to the invention to an electrophoretic display device. As another example, by employing, as the display element unit 12, a configuration of an EL display device comprising a number of EL elements, the electro-optical device according to the present invention can be applied to the EL display device.

As an EL display element, it is especially preferable to employ an organic EL element using an organic luminous layer. Specifically, a configuration in which a hole injection/transmitting layer, an organic luminous layer, and a cathode are laminated on an anode in the described order is used. Alternatively, an electron injection/transmitting layer can be provided between the organic luminous layer and the cathode.

In order to form the display element unit 12 including such organic EL elements between the plastic substrates 11 and 11, an active matrix TFT circuit is firstly formed on one of the plastic substrates 11, the same as the manufacturing method according to the above embodiment. After that, on the active matrix TFT circuit, an anode (pixel electrode) can be formed in a pattern corresponding to each pixel. Then, on the patterned circuit, a hole injection/transmitting layer and an organic luminous layer (electron injection/transmitting layer) are formed in the described order. Further, on the top of the layers, a cathode is formed by evaporation, and the like. Thus, an organic EL element is formed.

After forming the display element unit 12 by forming the organic EL element, as described above, the other plastic substrates 11 can be bonded and welded with, the same as in the manufacturing method according to the above embodiment, to obtain an EL display device (electro-optical device).

The organic luminous layer and the cathode of an organic EL display device are susceptible to moisture, and degraded with a contact to moisture, leading to a great degradation of display properties. However, the EL display device (electro-optical device) obtained in the above method has a high sealability and highly controls moisture infiltration, as described above. Therefore, excellent display performance can be maintained for a long time.

In addition, the electro-optical device according to the invention can also be applied to a liquid crystal display device.

Further, the sealing member 15 used in the above embodiment for enhancement of sealability is not necessary because, in the electro-optical device according to the present invention, sufficient sealability can be secured by means of welding. Furthermore, when the sealing member 15 is not used, the electro-optical device takes a configuration without any sealant, such as resin, etc., unlike the conventional device. This means that the display element unit is not subjected to contamination nor mixture of foreign materials due to the use of such a sealant. Therefore, the display element can provide excellent display performance.

In addition, since no sealant is used, there can be no problem, such as volatilization of sealant, etc., which especially contributes to a successive achievement of a series of manufacturing steps in a vacuum atmosphere: including formation of the display element unit, bonding, and welding. Therefore, productivity can be improved.

Besides, the wiring of the display element unit 12, which is drawn out from the through-hole formed on the plastic substrate 11 in the above exemplary embodiment, can be provided by, for example, drawing out the wiring from part of the periphery of the plastic substrates 11 and 11, which is left unwelded, and then sealing the same part with resin, etc. Even in such a case, better sealability compared to that in the conventional technique can be secured because the periphery of the plastic substrates 11 and 11 is basically sealed by welding.

Further, in the above exemplary embodiment, both of the pair of plastic substrates are flexible substrates. However, it should be understood that the plastic substrates are not limited to be flexible in the invention. One or both of the pair of plastic substrates can be made of a relatively hard material. In such a case, the advantages such as unbreakableness, lightness, etc. can still be maintained because the substrates are plastic.

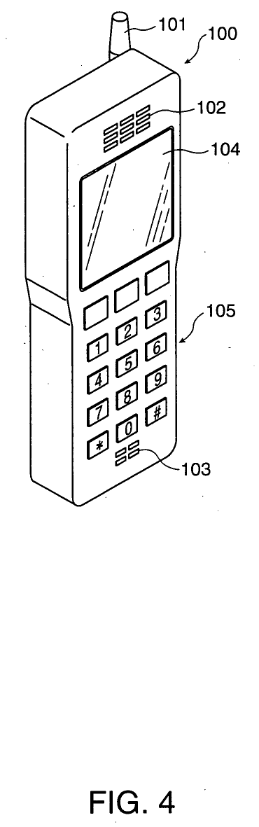

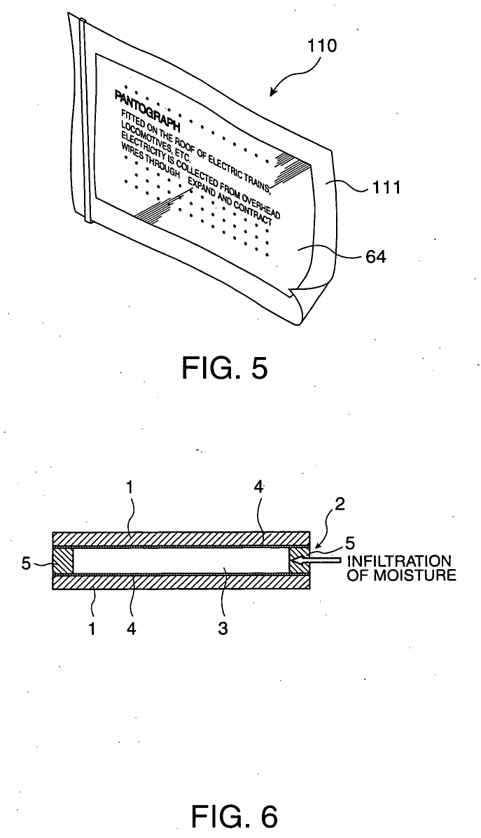

Next, an electronic device according to the invention will now be described. The electronic device according to the present invention is a device having the electro-optical device 10 (electrophoretic display device 20) as a display unit. Specifically, there are such devices as shown in FIG. 4 and FIG. 5.

FIG. 4 is a drawing of a cellular phone used as a portable information-processing device. A reference numeral 100 in FIG. 4 is a cellular phone handset. The cellular phone handset 100 can include an antenna 101, a receiver 102, a transmitter 103, a display 104 and an operation button unit 105, etc. Further, the display 104 is configured of the electro-optical device 10 (electrophoretic display device 20).

FIG. 5 is a perspective view of the configuration of an electronic paper. A reference numeral 110 in FIG. 5 is an electronic paper. The electronic paper 110 can include a main body 111, which has a paper-like texture and flexibility, and a display 64, which is configured of the electro-optical device 10 (electrophoretic display device 20).

Since such electronic devices employ the electro-optical device 10, which has a longer life as described above, as the display 104 (64), the life of such electronic devices can be prolonged as a whole, especially for the display 104 (64).

While this invention has been described in conjunction with the specific embodiments thereof, it is evident that many alternatives, modifications, and variations will be apparent to those skilled in the art. Accordingly, preferred embodiments of the invention as set forth herein are intended to be illustrative, not limiting. There are changes that may be made without departing from the spirit and scope of the invention.

1. An electro-optical device, comprising:
a pair of plastic substrates;
a display element disposed between the pair of plastic substrates; and
a periphery of the plastic substrates being sealed by welding.

2. The electro-optical device according to claim 1, a periphery of the pair of plastic substrates being entirely welded and sealed.

3. The electro-optical device according to claim 1, a low-moisture permeable film being provided on an inner surface of each of the pair of plastic substrates.

4. The electro-optical device according to claim 1, both of the pair of plastic substrates being flexible.

5. The electro-optical device according to claim 1, the display element being an electrophoretic element.

6. The electro-optical device according to claim 1, the display element being an EL element.

7. A method for manufacturing an electro-optical device having a pair of plastic substrates with a display element disposed in between, comprising:
bonding the pair of plastic substrates with the display element disposed in between; and
welding a periphery of the bonded pair of plastic substrates.

8. The method for manufacturing an electro-optical device according to claim 7, the welding being performed by at least one of laser irradiation and ultrasonication.

9. The method for manufacturing an electro-optical device according to claim 7, the pair of plastic substrates being welded with the periphery being clamped.

10. An electronic device, comprising:
the electro-optical device according to claim 1.

11. An electronic device, comprising:
the electro-optical device obtained by using the manufacturing method according to claim 7.
